(19) United States
(12) Patent Application Publication
(10) Pub. No.: US 2015/0206584 A1
(43) Pub. Date: Jul. 23, 2015

(54) CONTROLLING METHOD FOR SOLID STATE DRIVE WITH RESISTIVE RANDOM-ACCESS MEMORY

(71) Applicant: LITE-ON IT CORPORATION, Taipei (TW)

(72) Inventors: Song-Feng Tsai, Hsinchu (TW); Yi-Chung Lee, Hsinchu (TW)

(73) Assignee: LITE-ON IT CORPORATION, Taipei (TW)

(21) Appl. No.: 14/222,805

(22) Filed: Mar. 24, 2014

(30) Foreign Application Priority Data
Jan. 17, 2014 (CN) 201410022201.1

(51) Int. Cl. G11C 14/00; G06F 12/02

(52) U.S. Cl. CPC G11C 14/0045; G06F 12/0246; G06F 12/0253; G11C 13/0097

(57) ABSTRACT

A controlling method for a solid state drive is provided. The solid state drive includes a controlling circuit and a resistive random-access memory. Firstly, a monitor factor is defined. The monitor factor is associated with a life span of the resistive random-access memory. If the monitor factor is higher than a predetermined value, a mapping algorithm of a logical-to-physical table is established by the controlling circuit and a logical block address of a host is mapped to a physical allocation address by the controlling circuit according to the logical-to-physical table, and a data accessing action is performed.

This application claims the benefit of People's Republic of China Application Serial No. 201410022201.1, filed Jan. 17, 2014, the subject matter of which is incorporated herein by reference.

### FIELD OF THE INVENTION

The present invention relates to a controlling method for a solid state drive, and more particularly to a controlling method for a solid state drive with a resistive random-access memory (RRAM).

### BACKGROUND OF THE INVENTION

As is well known, a solid state drive (SSD) is a data storage device that uses a NAND-based flash memory to store data. The NAND-based flash memory is a non-volatile memory. After data are written to the flash memory, if no power is supplied to the flash memory, the data are still retained in the flash memory.

Generally, the flash memory comprises plural memory arrays. The memory array of the flash memory comprises plural memory cells. In addition, each memory cell has a floating gate transistor.

During a program cycle, hot carriers are selectively injected into a floating gate of the floating gate transistor, so that the storing state of the memory cell is changed. For example, if no hot carriers are injected into the floating gate, the memory cell has a first storing state. Whereas, if the hot carriers are injected into the floating gate, the memory cell has a second storing state. Moreover, during an erase cycle, all hot carriers are rejected from the floating gate of the floating gate transistor to perform the erasing action of the memory cell.

Generally, the life span of the floating gate transistor of the memory cell is related to the erase count. For example, a SLC flash memory may store one bit of data per cell, and the erase count of the SLC flash memory is about one hundred thousand. Moreover, a MLC flash memory may store two bits of data per cell, and the erase count of the MLC flash memory is about three thousand to ten thousand. Moreover, a TLC flash memory may store three bits of data per cell, and the erase count of the TLC flash memory is about five hundred to one thousand.

For prolonging the life span of the flash memory, various controlling methods for controlling the flash memory have been disclosed. When the solid state drive leaves the factory, these controlling methods are preset to be enabled to prolong the life span of the flash memory. These controlling methods comprise for example a mapping algorithm of a logical-to-physical table (L2P table), a wear leveling algorithm, a garbage collection algorithm, and the like. The contents of these controlling methods will be illustrated in more details as follows.

Generally, the flash memory comprises plural blocks. Each block contains plural pages (or sectors). For example, each block contains 64 pages. Each page is typically 4K bytes in size. Due to the inherent properties of the flash memory, at least one page is written at a time during the writing operation, and the erasing operation is performed in a block-wise fashion.

Since at least one page is written into the flash memory at a time during the writing operation, some drawbacks may occur. After the flash memory has been accessed for a long time, each block of the flash memory may contain some valid pages and some invalid pages. Since the erasing operation of the flash memory is performed in the block-wise fashion, the block containing the valid pages cannot be erased. If the space of the flash memory is occupied by a great number of invalid data, the writable space of the flash memory is gradually reduced.

As the garbage collection algorithm is enabled when the solid state drive leaves the factory, the controlling circuit of the solid state drive may perform a garbage collection action at an appropriate time according to the change of the writable space of the flash memory.

The garbage collection action is a process of collecting valid pages of an old block and storing the valid pages into another new block by the controlling circuit of the solid state drive. After the valid pages are collected and restored, the pages of the old block are all changed into the invalid pages, so that the old block may be erased and reused as a free block. Under this circumstance, the writable space of the flash memory is enhanced.

Generally, each memory cell of the flash memory has limited erase count. If some specified blocks have high erase counts, these blocks are overused and possibly become bad blocks. Under this circumstance, the life span of the flash memory may be reduced. For solving the above drawbacks, a wear leveling technique is disclosed. According to the wear leveling technique, all blocks of the flash memory are averagely used. In other words, the use of the wear leveling technique may prolong the life span of the flash memory.

As the wear leveling algorithm is enabled when the solid state drive leaves the factory, the controlling circuit of the solid state drive may monitor the erase count of each block, and perform a wear leveling action at an appropriate time. In other words, while the wear leveling action is performed, data exchange between the blocks with lower erase counts and the blocks with higher erase counts will be done.

Generally, the host may access the data of the solid state drive through logical block addresses (LBA). The flash memory accesses data through physical allocation addresses (PAA).

Moreover, for correlating the LBA with the PAA, the mapping algorithm of the logical-to-physical address table (L2P table) is established in the solid state drive. For example, when the host issues a read command to read a data from a specified LBA of the flash memory, the PAA of data in the flash memory is realized by the controlling circuit of the solid state drive according to the L2P table, and then the data is transmitted back from the flash memory to the host.

When the solid state drive is normally powered on, the mapping algorithm of the L2P table is firstly established by the controlling circuit of the solid state drive. After the mapping algorithm of the L2P table is established, the host and the solid state drive can normally access data. Generally, as the data amount of the L2P table increases with the increase of the capacity of the flash memory, the accessing performance of the flash memory decreases.

From the above discussions, the mapping algorithm of the L2P table, the wear leveling algorithm and the garbage collection algorithm are present to be enabled to prolong the life span of the flash memory when the solid state drive leaves the factory. However, the above algorithms may decrease the accessing performance of the solid state drive.

### SUMMARY OF THE INVENTION

An embodiment of the present invention provides a controlling method for a solid state drive. The solid state drive includes a controlling circuit and a resistive random-access memory as a primary storing media. Firstly, a monitor factor is defined. The monitor factor is associated with a life span of the resistive random-access memory. If the monitor factor is higher than a predetermined value, a mapping algorithm of a logical-to-physical table is established by the controlling circuit and a logical block address of a host is mapped to a physical allocation address by the controlling circuit according to the logical-to-physical table, and a data accessing action is performed.

Another embodiment of the present invention provides a controlling method for a solid state drive. The solid state drive includes a controlling circuit and a resistive random-access memory as a primary storing media. Firstly, a monitor factor is defined. The monitor factor is associated with a life span of the resistive random-access memory. If the monitor factor is higher than a predetermined value, a mapping algorithm of a logical-to-physical table, a wear leveling algorithm and/or a garbage collection algorithm are selectively enabled by the controlling circuit.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic circuit diagram illustrates a resistive random-access memory;

FIG. 2 is a schematic functional block diagram illustrating a solid state drive according to an embodiment of the present invention; and

FIG. 3 is a flowchart illustrating a controlling method for a solid state drive with a resistive random-access memory according to an embodiment of the present invention.

### DETAILED DESCRIPTION OF PREFERRED EMBODIMENTS

Recently, a solid state drive with variable resistors as the main storage element has been introduced into the market. This storage element is also referred as a resistive random-access memory (RRAM). The resistive random-access memory is one kind of non-volatile memory.

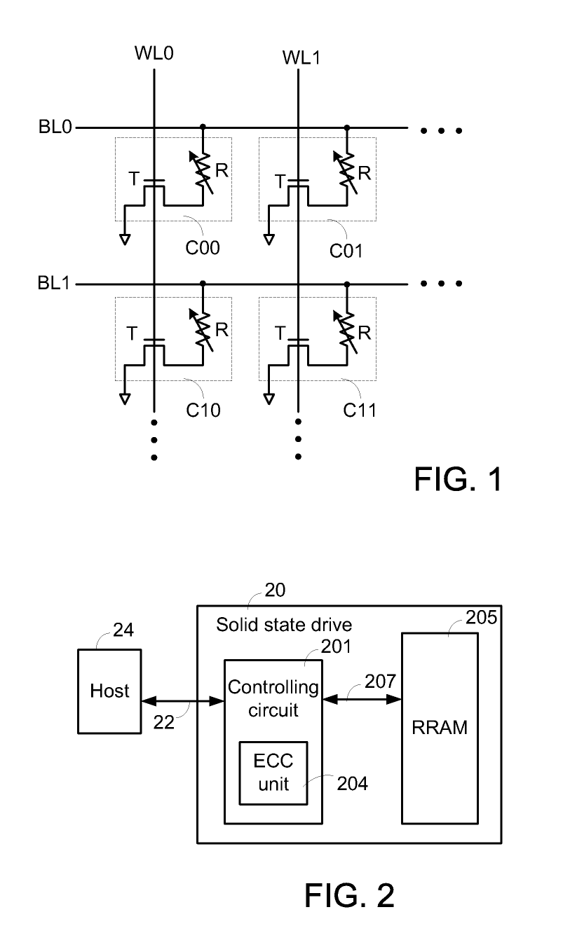

FIG. 1 is a schematic circuit diagram illustrates a resistive random-access memory. As shown in FIG. 1, the memory array of the resistive random-access memory comprises four memory cells C00, C01, C10 and C11. The memory cells C00, C01, C10 and C11 have similar cell architectures and program functions. Take memory cell C00 as an example, the memory cell C00 comprises a selective transistor T and a variable resistor R. The gate of the selective transistor T is connected to a zero-th word line WL0. The source terminal of the selective transistor T is connected to a ground terminal. A first end of the variable resistor R is connected to a drain terminal of the selective transistor T. A second end of the variable resistor R is connected to a zero-th bit line BL0.

During a program cycle, a program voltage is provided to change the resistance value of the variable resistor R. For example, if the variable resistor R is programmed to have a high resistance value, the memory cell COO has a first storing state. Whereas, if the variable resistor R is programmed to have a low resistance value, the memory cell COO has a second storing state. Moreover, during an erase cycle, the resistance value of the variable resistor R is restored to the identical value to perform the erasing action of the memory cell.

In comparison with the memory cell of the flash memory using the floating gate transistor, the erase count of the memory cell of the resistive random-access memory is up to several hundred thousand or over one million. In other words, the life span of the resistive random-access memory is much longer than the flash memory. Therefore, it is important to increase the accessing performance of the resistive random-access memory.

FIG. 2 is a schematic functional block diagram illustrating a solid state drive according to an embodiment of the present invention. As shown in FIG. 2, the solid state drive 20 comprises a controlling circuit 201 and a resistive random-access memory 205. The controlling circuit 201 and the resistive random-access memory 205 are in communication with each other through an internal bus 207. The controlling circuit 201 is in communication with a host 24 through an external bus 22. Consequently, commands and data can be exchanged between the controlling circuit 201 and the host 24. Generally, the external bus 22 is a USB bus, an IEEE 1394 bus, an SATA bus, or the like.

The controlling circuit 201 further comprises an error correction (ECC) unit 204. When the host 24 intends to write the write data into the resistive random-access memory 205, an error correction code (ECC code) is correspondingly generated by the ECC unit 204. Then, the write data and the ECC code are written into the resistive random-access memory 205. When the host 24 intends to read the read data from the resistive random-access memory 205, the read data and the corresponding ECC code are inputted into the controlling circuit 201. After the error is corrected by the ECC unit 204, the accurate read data can be transmitted from the controlling circuit 201 to the host 24.

Generally, the operating status of the resistive random-access memory 205 can be acquired by the controlling circuit 201 according to the operations of the ECC unit 204. For example, during the process of outputting the read data, the ECC unit 204 may generate correctable errors and non-correctable errors. Accordingly, the controlling circuit 201 may realize the operating status of the resistive random-access memory 205.

For enhancing the accessing performance of the resistive random-access memory 205 and prolonging the life span of the resistive random-access memory 205, the present invention provides a controlling method for the solid state drive 20 with the resistive random-access memory 205. While the solid state drive 20 leaves the factory, a monitor factor associated with a life span of the resistive random-access memory 205 is constructed. During operations of the solid state drive 20, different control algorithms are selectively enabled by the controlling circuit 201 according to the monitor factor. In one embodiment, the different control algorithms related to the mechanisms of prolonging the life span may be preset to be disabled while the solid state drive 20 leaves the factory. In other embodiment, the different control algorithms related to the mechanisms of prolonging the life span may be controlled to be enabled or disabled by the controlling circuit 201 according to the monitor factor.

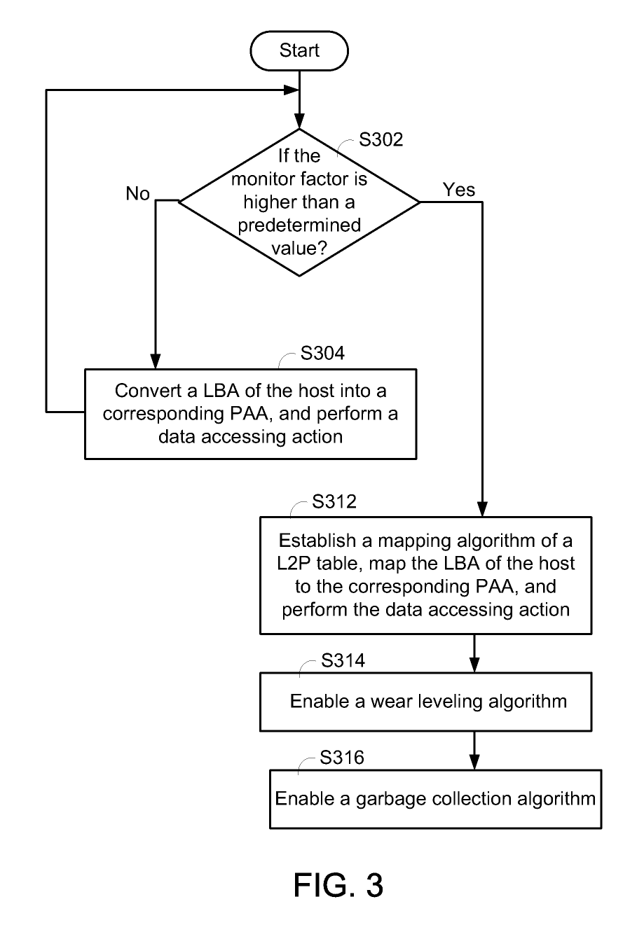

FIG. 3 is a flowchart illustrating a controlling method for a solid state drive with a resistive random-access memory according to an embodiment of the present invention. Firstly, the controlling circuit 201 judges whether the monitor factor is higher than a predetermined value (Step S302).

If the monitor factor is not higher than the predetermined value, it means that the residual life of the resistive random-access memory 205 is still very long. Under this circumstance, the accessing performance of the resistive random-access memory 205 is taken into consideration. Consequently, the logical block address (LBA) of the host 24 is directly converted into a corresponding physical allocation address (PAA) by the controlling circuit 201, and the data accessing action is performed (Step S304).

In the step S304, the logical block address (LBA) may be directly used as the physical allocation address (PAA) by the controlling circuit 201, and the data accessing action is performed according to the read commands or the write commands of the host 24. Alternatively, after the logical block address (LBA) is subjected to a mathematic operation by the controlling circuit 201, the logical block address (LBA) is converted into the corresponding physical allocation address (PAA), and then the data accessing action is performed according to the read commands or the write commands of the host 24.

On the other hand, if the monitor factor is higher than the predetermined value, it means that the residual life of the resistive random-access memory 205 is not long. Under this circumstance, the mechanisms of prolonging the life span of the resistive random-access memory 205 should be taken into consideration. Generally, the mechanisms for prolonging the life span of the memory cells may decrease the accessing performance of the resistive random-access memory 205. Consequently, a mapping algorithm of a logical-to-physical address table (L2P table) is established by the controlling circuit 201, the logical block address (LBA) of the host 24 is mapped to the corresponding physical allocation address (PAA) by the controlling circuit 201, and the data accessing action is performed (Step S312).

For example, in case that the solid state drive 20 is normally operated and the monitor factor is higher than the predetermined value, the mapping algorithm of the L2P table is firstly established by the controlling circuit 201. When a read command or a write command is issued from the host 24 to the solid state drive 20, the logical block address (LBA) of the host 24 is mapped to the corresponding physical allocation address (PAA) by the controlling circuit 201 according to the L2P table. Afterwards, the data accessing action is performed

Moreover, for effectively prolonging the life span of the resistive random-access memory 205, a wear leveling algorithm is enabled (Step 314) and a garbage collection algorithm is enabled (Step S316).

After the wear leveling algorithm is enabled, the controlling circuit 201 may monitor the erase count of each block, and perform a wear leveling action at an appropriate time. In other words, while the wear leveling action is performed, data exchange between the blocks with lower erase counts and the blocks with higher erase counts will be done.

After the garbage collection algorithm is enabled, the controlling circuit 201 may perform a garbage collection action at an appropriate time according to the change of the writable space of the resistive random-access memory 205. The garbage collection action is a process of collecting valid pages of an old block and storing the valid pages into another new block. After the valid pages are collected and restored, the pages of the old block are all changed into the invalid pages, so that the old block may be erased and reused as a free block. Under this circumstance, the writable space of the resistive random-access memory 205 is enhanced.

It is noted that numerous modifications and alterations may be made while retaining the teachings of the invention. For example, in some other embodiments, the mapping algorithm of the L2P table, the wear leveling algorithm and the garbage collection algorithm are selectively enabled by the controlling circuit 201 according to the relationship between the monitor values of these algorithms and different predetermined values.

Please refer to the embodiment of FIG. 3 again. If the monitor factor is not higher than the predetermined value, it means that the residual life of the resistive random-access memory 205 is still very long. Therefore, it prefers to enhance the accessing performance than prolong the span life of the resistive random-access memory 205. Under this circumstance, the accessing performance of the resistive random-access memory 205 is taken into consideration. Meanwhile, the mapping algorithm of the L2P table, the wear leveling algorithm and/or the garbage collection algorithm are disabled by the controlling circuit 201. On the other hand, if the monitor factor is higher than the predetermined value, it means that the residual life of the resistive random-access memory 205 is not long. Therefore, it prefers to prolong the span life than enhance the accessing performance of the resistive random-access memory 205. Under this circumstance, the mechanisms of prolonging the life span of the resistive random-access memory 205 should be taken into consideration. Meanwhile, the mapping algorithm of the L2P table, the wear leveling algorithm and/or the garbage collection algorithm are enabled by the controlling circuit 201.

In accordance with the present invention, the monitor factor is a parameter selected from at least one of an erase count of a specified block, a read count of the specified block, a write count of the specified block, an operating temperature of the solid state drive, an accessing frequency of the solid state drive, a cycle of writing data to the same memory cell, the number of correctable errors and the number of non-correctable errors.

From the above discussions, the present invention provides a controlling method for a solid state drive with a resistive random-access memory. In accordance with the present invention, the operating status of the resistive random-access memory is judged according to a monitor factor, which is associated with the life span of the resistive random-access memory. Before the monitor factor reaches the predetermined value, the residual life of the resistive random-access memory 205 is still very long. Under this circumstance, mapping algorithm of the L2P table, the wear leveling algorithm and the garbage collection algorithm are not enabled by the controlling circuit 201. Consequently, the solid state drive 20 has optimal accessing performance.

When the monitor factor reaches the predetermined value, the mechanisms of prolonging the life span of the resistive random-access memory 205 should be taken into consideration. Under this circumstance, the mapping algorithm of the L2P table, the wear leveling algorithm and the garbage collection algorithm are selectively enabled by the controlling circuit 201. Although the solid state drive 20 is not optimized at this moment, the life span of the solid state drive 20 can be effectively prolonged.

However, those skilled in the art will readily observe that the controlling method of the present invention may be modified while retaining the teachings of the invention. For example, when the monitor factor reaches the predetermined value, only one or two of the steps S312, S314 and S316 are performed. In this way, the purpose of prolonging the life span of the solid state drive is still achievable.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A controlling method for a solid state drive, the solid state drive comprising a controlling circuit and a resistive random-access memory as a primary storing media, the controlling method comprising steps of:
defining a monitor factor, which is associated with a life span of the resistive random-access memory; and
judging whether the monitor factor is higher than a predetermined value, wherein if the monitor factor is higher than the predetermined value, a mapping algorithm of a logical-to-physical table is established by the controlling circuit and a logical block address of a host is mapped to a physical allocation address by the controlling circuit according to the logical-to-physical table, and a data accessing action is performed.

2. The controlling method as claimed in claim 1, wherein if the monitor factor is not higher than the predetermined value, the logical block address of the host is directly converted into the physical allocation address by the controlling circuit, and the data accessing action is performed.

3. The controlling method as claimed in claim 1, wherein if the monitor factor is higher than the predetermined value, the controlling method further comprises a step of enabling a wear leveling algorithm by the controlling circuit.

4. The controlling method as claimed in claim 3, wherein after the wear leveling algorithm is enabled, the controlling circuit performs a wear leveling action to monitor erase counts of plural blocks of the resistive random-access memory, wherein data exchange between the blocks with lower erase counts and the blocks with higher erase counts is done.

5. The controlling method as claimed in claim 1, wherein if the monitor factor is not higher than the predetermined value, the controlling method further comprises a step of disabling a wear leveling algorithm by the controlling circuit.

6. The controlling method as claimed in claim 1, wherein if the monitor factor is higher than the predetermined value, the controlling method further comprises a step of enabling a garbage collection algorithm.

7. The controlling method as claimed in claim 6, wherein after the garbage collection algorithm is enabled, the controlling circuit performs a garbage collection action to collect plural valid pages of plural blocks of the resistive random-access memory into a new block according to a change of a writable space of the resistive random-access memory, wherein the plural valid pages of the plural blocks are all changed into invalid pages.

8. The controlling method as claimed in claim 7, wherein the controlling circuit further performs an erasing action to erase all invalid pages, thereby generating plural free blocks.

9. The controlling method as claimed in claim 1, wherein if the monitor factor is not higher than the predetermined value, the controlling method further comprises a step of disabling a garbage collection algorithm.

10. The controlling method as claimed in claim 1, wherein the monitor factor is a parameter selected from at least one of an erase count of a specified block, a read count of the specified block, a write count of the specified block, an operating temperature of the solid state drive, an accessing frequency of the solid state drive, a cycle of writing data to the same memory cell of the solid state drive, a number of correctable errors and a number of non-correctable errors.

11. A controlling method for a solid state drive, the solid state drive comprising a controlling circuit and a resistive random-access memory as a primary storing media, the controlling method comprising steps of:
defining a monitor factor, which is associated with a life span of the resistive random-access memory; and
judging whether the monitor factor is higher than a predetermined value,
wherein if the monitor factor is higher than the predetermined value, a mapping algorithm of a logical-to-physical table, a wear leveling algorithm and/or a garbage collection algorithm are selectively enabled by the controlling circuit.

12. The controlling method as claimed in claim 11, wherein when the monitor factor is not higher than the predetermined value, the mapping algorithm of the logical-to-physical table, the wear leveling algorithm and/or the garbage collection algorithm are disabled.

13. The controlling method as claimed in claim 11, wherein after the mapping algorithm of the logical-to-physical table is enabled, a logical block address of a host is mapped to a physical allocation address by the controlling circuit according to the logical-to-physical table, and a data accessing action is performed.

14. The controlling method as claimed in claim 11, wherein after the wear leveling algorithm is enabled, the controlling circuit performs a wear leveling action to monitor erase counts of plural blocks of the resistive random-access memory, wherein data exchange between the blocks with lower erase counts and the blocks with higher erase counts is done.

15. The controlling method as claimed in claim 11, wherein after the garbage collection algorithm is enabled, the controlling circuit performs a garbage collection action to collect plural valid pages of plural blocks of the resistive random-access memory into a new block according to a change of a writable space of the resistive random-access memory, wherein the plural valid pages of the plural blocks are all changed into invalid pages.

16. The controlling method as claimed in claim 11, wherein the monitor factor is a parameter selected from at least one of an erase count of a specified block, a read count of the specified block, a write count of the specified block, an operating temperature of the solid state drive, an accessing frequency of the solid state drive, a cycle of writing data to the same memory cell of the solid state drive, a number of correctable errors and a number of non-correctable errors.
